(19) United States
(12) Patent Application Publication
(10) Pub. No.: US 2025/0006834 A1
(43) Pub. Date: Jan. 2, 2025

(54) SEMICONDUCTOR DEVICE AND FABRICATION METHOD THEREOF

(71) Applicant: Vanguard International Semiconductor Corporation, Hsinchu (TW)

(72) Inventors: Wen-Shan Lee, Hsinchu City (TW); Chung-Yeh Lee, Hsinchu County (TW); Fu-Hsin Chen, Hsinchu County (TW)

(73) Assignee: Vanguard International Semiconductor Corporation, Hsinchu (TW)

(21) Appl. No.: 18/215,819

(22) Filed: Jun. 28, 2023

(51) Int. Cl. H01L 29/78; H01L 29/06; H01L 29/66

(52) U.S. Cl. CPC H01L 29/7811; H01L 29/0607; H01L 29/0696; H01L 29/66734; H01L 29/7813

(57) ABSTRACT

A semiconductor device includes a substrate having a first conductivity type and including a cell region and a termination region. A trench is disposed in the substrate and located in the cell region, and a gate electrode disposed in the trench. A shielding doped region having a second conductivity type is disposed in the substrate and directly below the trench. A buried guard ring having the second conductivity type is disposed in the substrate and located in the termination region. The buried guard ring and the shielding doped region are disposed at the same depth in the substrate. In addition, a junction termination extension structure having the second conductivity type is disposed in the substrate, located directly above and separated from the buried guard ring.

### BACKGROUND OF THE INVENTION

### 1. Field of the Invention

The present disclosure relates to semiconductor technology, and more particularly to semiconductor devices including trench power transistors with termination structures and fabrication methods thereof.

### 2. Description of the Prior Art

Power transistors are usually used as power components such as power switches and converters in power electronic systems. Power transistors are typically operated under high voltage and high current conditions. Power diodes, metal-oxide-semiconductor field-effect-transistors (MOSFETs), insulated-gate bipolar transistors (IGBTs) are common power transistors used in power electronic systems. In general, power transistors require a termination structure disposed at the edges thereof to avoid electric field accumulation at the edges of the main p-n junction and prevent a breakdown of the power transistors at a relatively low breakdown voltage.

The termination structure may include different forms such as field plates, floating guard rings, and junction termination extensions. However, the conventional termination structures usually require a larger termination edge width, which means a larger die size, to achieve the high breakdown voltage required for the power transistors. In addition, the breakdown voltage of the power transistor is easily width of the conventional floating guard ring. Therefore, for the power transistors, the conventional termination structures still cannot fully satisfy the various requirements in power electronic applications, such as the requirements for breakdown voltage, die size, sensitivity to the process, etc.

### SUMMARY OF THE INVENTION

In view of this, the present disclosure provides semiconductor devices and fabrication methods thereof, which include a junction termination extension structure and a buried guard ring disposed in a termination region of a substrate, so as to reduce the surface electric field at the end of the main junction and the edges of the termination structure, and to extend the depletion region. Therefore, the termination edge width of the semiconductor devices is greatly decreased to effectively reduce the die size. In addition, the sensitivity of the breakdown voltage of the semiconductor devices to the spacing width of the buried guard ring is reduced, thereby enlarging the process window of fabricating the semiconductor devices.

According to an embodiment of the present disclosure, a semiconductor device is provided and includes a substrate, a trench, a gate electrode, a shielding doped region, a buried guard ring, and a junction termination extension structure. The substrate has a first conductivity type and includes a cell region and a termination region. The trench is disposed in the substrate and located in the cell region. The gate electrode is disposed in the trench. The shielding doped region has a second conductivity type and is disposed in the substrate and directly under the trench. The buried guard ring has the second conductivity type and is disposed in the substrate and located in the termination region, where the buried guard ring and the shielding doped region are at the same depth in the substrate. The junction termination extension structure has the second conductivity type and is disposed in the substrate and directly above the buried guard ring, where the junction termination extension structure is separated from the buried guard ring.

According to an embodiment of the present disclosure, a method of fabricating a semiconductor device is provided and includes the following steps. A substrate is provided and includes an epitaxial layer having a first conductivity type, where the substrate includes a cell region and a termination region. An ion implantation process is performed on the epitaxial layer to form a shielding doped region in the cell region, and to form a buried guard ring and a junction termination extension structure in the termination region, where the junction termination extension structure is located directly above the buried guard ring and separated from the buried guard ring. The shielding doped region, the buried guard ring, and the junction termination extension structure all have a second conductivity type. A trench is formed in the epitaxial layer and located in the cell region. In addition, a gate electrode is formed in the trench.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a semiconductor device according to an embodiment of the present disclosure.

FIG. 2 is a schematic cross-sectional view of a semiconductor device according to another embodiment of the present disclosure.

FIG. 3, FIG. 4, FIG. 5, FIG. 6, FIG. 7 and FIG. 8 are schematic cross-sectional views of some stages of a method of fabricating a semiconductor device according to an embodiment of the present disclosure.

FIG. 9 shows schematic cross-sectional views of some intermediate stages of a method of fabricating a semiconductor device according to another embodiment of the present disclosure.

FIG. 10 shows schematic cross-sectional views of some intermediate stages of a method of fabricating a semiconductor device according to further another embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to semiconductor devices and fabrication methods thereof, which include trench power transistors having termination structures. The termination structures include a junction termination extension (JTE) structure and a buried guard ring disposed in a termination region of a substrate, which effectively reduce the surface electric field at the end of the main junction and at the edges of the termination structures of the semiconductor devices, and extend the overall depletion region. Therefore, the termination edge width of the semiconductor device is greatly decreased to effectively reduce the die area under the same breakdown voltage. Moreover, the sensitivity of the breakdown voltage of the semiconductor device to the spacing width of the buried guard ring is reduced, thereby enlarging the process window of fabricating the semiconductor device. In addition, the buried guard ring and a shielding doped region located directly below the trench are formed simultaneously by the same ion implantation process using the same photo mask, thereby saving the numbers of photo masks and the process steps, and reducing the cost of fabricating the semiconductor devices.

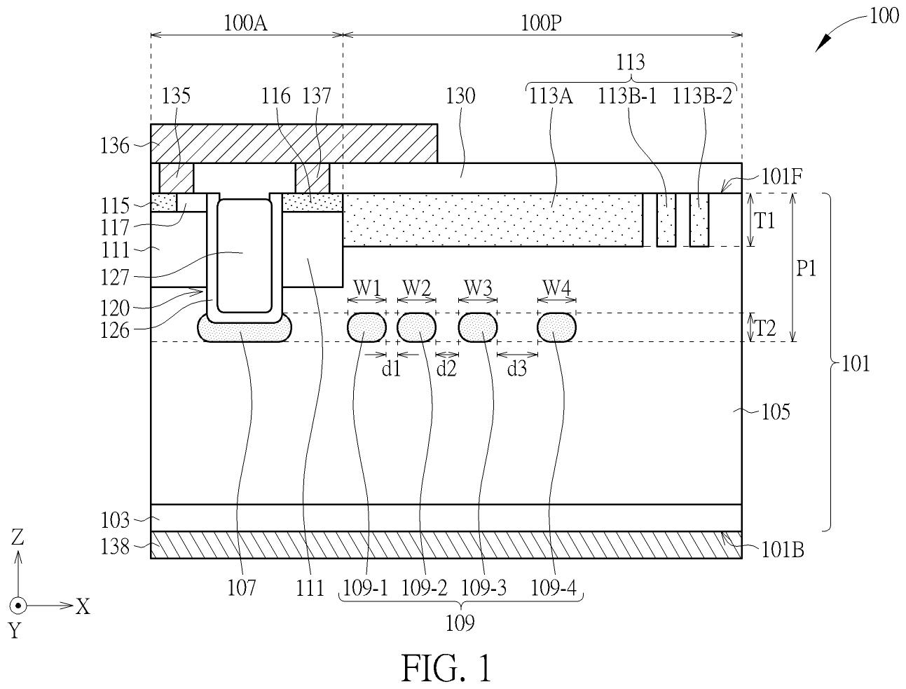

FIG. 1 is a schematic cross-sectional view of a semiconductor device according to an embodiment of the present disclosure. The semiconductor device 100 includes a substrate 101 having a first surface 101F (for example, a front surface) and a second surface 101B (for example, a back surface) opposite to the first surface 101F. The substrate 101 includes a cell region 100A and a termination region 100P. In some embodiments, the composition of the substrate 101 is, for example, silicon carbide (Sic), to facilitate the fabrication of power transistors such as MOSFETs. The substrate 101 includes a drain contact region 103 disposed on the second surface 101B thereof. The drain contact region 103 has a first conductivity type, such as an N-type heavily doped region (N⁺). The substrate 101 further includes an epitaxial layer 105 disposed on the drain contact region 103. The epitaxial layer 105 has the first conductivity type, such as an N-type lightly doped SiC epitaxial layer (N⁻ Epi). In one embodiment, the substrate 101 having the first conductivity type is, for example an N-type SiC substrate. The semiconductor device 100 may include a trench gate MOSFET, where a trench 120 is disposed in the substrate 101 and located in the cell region 100A. A gate electrode 127 is disposed in the trench 120, and a gate dielectric layer 126 is conformally disposed on the sidewalls and the bottom surface of the trench 120 to surround the gate electrode 127. The semiconductor device 100 further includes a well region 111 disposed in the substrate 101 and located in the cell region 100A. The well region 111 having a second conductivity type is, for example a P-type well region (PW), which abuts the sides of the trench 120 and surrounds the trench 120. A source contact region 117 is disposed in the well region 111 and located on the first surface 101F of the substrate 101. The source contact region 117 having the first conductivity type is, for example an N-type heavily doped region (N⁺). In addition, a bulk contact region 115 is also disposed in the well region 111 and abuts the source contact region 117. The bulk contact region 115 having the second conductivity type is, for example a P-type heavily doped region (P⁺). The source contact region 117 and the bulk contact region 115 are located on the same side of the trench 120. In addition, a heavily doped region 116 having the second conductivity type is, for example a P-type heavily doped region (P⁺), which is disposed in the well region 111 and located on the other side of the trench 120. An interlayer dielectric (ILD) layer 130 is formed on the first surface 101F of the substrate 101, and multiple vias 135 and 137 are formed in the ILD layer 130, where the via 135 is electrically connected to the source contact region 117 and the bulk contact region 115, and the other via 137 is electrically connected to the heavily doped region 116. A source electrode 136 is formed on the ILD layer 130 and electrically coupled to the source contact region 117 and the bulk contact region 115 through the via 135, and further electrically coupled to the heavily doped region 116 through the other via 137. In some embodiments, during the operation of the semiconductor device 100, the source electrode 136 may be electrically coupled to a ground terminal, so that the source contact region 117, the bulk contact region 115, and the heavily doped region 116 are all electrically coupled to the ground terminal. In addition, a drain electrode 138 is formed on the second surface 101B of the substrate 101 and electrically connected to the drain contact region 103.

Still referring to FIG. 1, the semiconductor device 100 further includes a shielding doped region 107 disposed in the substrate 101, located in the cell region 100A and directly below the trench 120. The shielding doped region 107 having the second conductivity type is, for example, a P-type heavily doped region (P⁺). In addition, according to some embodiments of the present disclosure, the semiconductor device 100 includes a buried guard ring 109 disposed in the substrate 101 and located in the termination region 100P. The buried guard ring 109 having the second conductivity type is, for example a P-type heavily doped region. The buried guard ring 109 and the shielding doped region 107 are substantially at the same depth P1 in the substrate 101. The buried guard ring 109 may include multiple laterally separated ring-shaped doped regions, such as four ring-shaped doped regions 109-1, 109-2, 109-3 and 109-4 spaced apart from each other along a first direction (for example, a X-axis direction), but not limited thereto, the buried guard ring 109 may include other numbers of ring-shaped doped regions. When viewed from a top view, these ring-shaped doped regions 109-1, 109-2, 109-3 and 109-4 all surround the cell region 100A. These ring-shaped doped regions may independently have a continuous or discontinuous ring shape on a plane (for example, a XY plane). In one embodiment, the widths W1, W2, W3 and W4 of these ring-shaped doped regions 109-1, 109-2, 109-3 and 109-4 may be the same, and the spacing widths d1, d2 and d3 of these ring-shaped doped regions 109-1, 109-2, 109-3 and 109-4 may be increased gradually along the first direction (for example, the X-axis direction) from the cell region 100A to the termination region 100P. In another embodiment, the widths W1, W2, W3 and W4 of these ring-shaped doped regions 109-1, 109-2, 109-3 and 109-4 may be the same, and the spacing widths d1, d2 and d3 of these ring-shaped doped regions 109-1, 109-2, 109-3 and 109-4 may also be the same. In other embodiments, the widths W1, W2, W3 and W4 of these ring-shaped doped regions 109-1, 109-2, 109-3 and 109-4 may be different from each other, and the spacing widths d1, d2 and d3 of these ring-shaped doped regions 109-1, 109-2, 109-3 and 109-4 may also be different from each other. The respective widths and the respective spacing widths of the multiple ring-shaped doped regions of the buried guard ring 109 may be adjusted based on the electric field distribution of the semiconductor device 100 to effectively reduce the surface electric field at the termination region 100P of the semiconductor device 100, thereby enhancing the breakdown voltage to facilitate the operation of the semiconductor device 100 under high voltages. According to some embodiments of the present disclosure, the doping concentrations of the ring-shaped doped regions 109-1, 109-2, 109-3 and 109-4 of the buried guard ring 109 are all the same as the doping concentration of the shielding doped region 107. In addition, the shielding doped region 107 and the buried guard ring 109 are laterally separated in the first direction (for example, the X-axis direction), and the buried guard ring 109 and the shielding doped region 107 may have substantially the same thickness T2.

Still referring to FIG. 1, the semiconductor device 100 further includes a junction termination extension (JTE) structure 113 disposed in the substrate 101. The JTE structure 113 is formed on the first surface 101F of the substrate 101 and located in the termination region 100P. The JTE structure 113 having the second conductivity type is, for example a P-type doped region. In one embodiment, the doping concentration of the JTE structure 113 may be lower than the doping concentration of the buried guard ring 109. The JTE structure 113 is located directly above the buried guard ring 109, and the JTE structure 113 and the buried guard ring 109 are separated from each other in a second direction (for example, a Z-axis direction). In one embodiment, the JTE structure 113 includes an inner doped region 113A and multiple laterally separated outer doped regions, such as two outer doped regions 113B-1 and 113B-2 separated from each other in the first direction (for example, the X-axis direction), but not limited thereto, the JTE structure 113 may include other numbers of outer doped regions. The inner doped region 113A and these outer doped regions 113B-1 and 113B-2 have substantially the same doping concentration. When viewed from a top view, the inner doped region 113A and these laterally separated outer doped regions 113B-1 and 113B-2 of the JTE structure 113 are disposed on one side of the cell region 100A. The inner doped region 113A and these laterally separated outer doped regions 113B-1 and 113B-2 may independently have a continuous or discontinuous strip shape in a third direction (for example, a Y-axis direction). In addition, in some embodiments, the vertical projection areas of these laterally separated outer doped regions 113B-1 and 113B-2 are outside the vertical projection area of the buried guard ring 109, i.e., the projection area of the outer doped regions 113B-1 and 113B-2 is outside the projection area of the buried guard ring 109 on the XY plane. Moreover, in one embodiment, the outermost edge of the inner doped region 113A is farther away from the cell region 100A than the outermost edge of the buried guard ring 109, i.e., the distance between the cell region 100A and the edge of the inner doped region 113A adjacent to the outer doped region 113B-1 is greater than the distance between the cell region 100A and the outer edge of the ring-shaped doped region 109-4 of the buried guard ring 109. According to an embodiment of the present disclosure, the outer doped regions 113B-1 and 113B-2 of the JTE structure 113 may further reduce the surface electric field at the edge of the termination region 100P, which facilitates to retard the sensitivity of the breakdown voltage to the doping concentration of the JTE structure 113. Therefore, the doping concentration of the JTE structure 113 may be lower than that of the buried guard ring 109. Furthermore, in one embodiment, the thickness T1 of the JTE structure 113 may be greater than the thickness T2 of the buried guard ring 109. During the operation of the semiconductor device 100, both the buried guard ring 109 and the JTE structure 113 may be electrically coupled to the source electrode 136 through other vias (not shown) that pass through the LID layer 130 and the epitaxial layer 105, or electrically coupled to a ground terminal through other wires (not shown).

According to some embodiments of the present disclosure, the overall depletion region is extended and enlarged through the depletion region generated by the JTE structure 113 combined with the depletion region generated by the buried guard ring 109, thereby effectively reducing the electric field at the end of the main junction of the cell region 100A. For example, the electric field at the interface between the cell region 100A and the termination region 100P and the electric field at the end of the junction between the P-type well region 111 and the N-type epitaxial layer 105 are reduced, and the surface electric field at the termination region 100P is also effectively reduced. Therefore, the required width of the termination region 100P of the semiconductor device 100 is greatly shortened under the condition of maintaining the same breakdown voltage, i.e., the widths of the short sides of the termination region 100P in both X-axis and Y-axis directions are greatly shortened, thereby reducing the die area.

In addition, according to some embodiments of the present disclosure, since the JTE structure 113 is disposed on the first surface 101F of the substrate 101, and the area of the JTE structure 113 is larger than that of the buried guard ring 109, through the combination of the JTE structure 113 and the buried guard ring 109, the sensitivity of the breakdown voltage to the spacing widths of the ring-shaped doped regions 109-1, 109-2, 109-3 and 109-4 of the buried guard ring 109 is reduced, thereby enlarging the process window of fabricating the semiconductor device 100. In addition, according to some embodiments of the present disclosure, the buried guard ring 109 and the shielding doped region 107 may be formed simultaneously by the same ion implantation process using the same photo mask, thereby saving the cost of fabricating the semiconductor device 100 and simplifying the process steps.

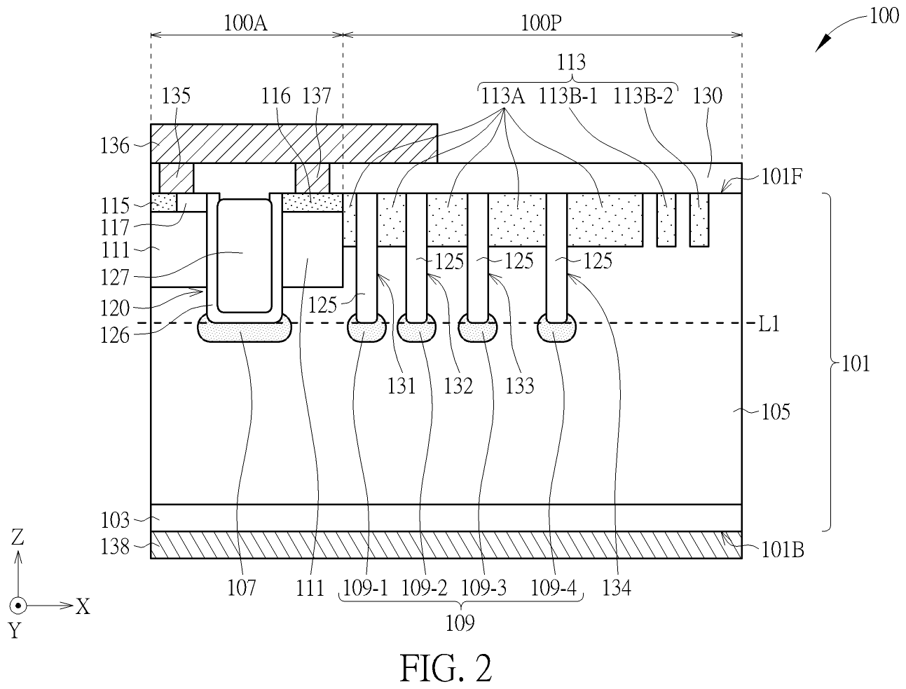

FIG. 2 is a schematic cross-sectional view of a semiconductor device according to another embodiment of the present disclosure. In addition to the features of the semiconductor device 100 of FIG. 1, the semiconductor device 100 of FIG. 2 further includes multiple trench isolation structures disposed in the substrate 101 and located in the termination region 100P, such as four trench isolation structures 131, 132, 133, 134 as shown in FIG. 2, but not limited thereto, the semiconductor device 100 may include other numbers of trench isolation structures. These trench isolation structures 131, 132, 133 and 134 are correspondingly disposed directly above the laterally separated ring-shaped doped regions 109-1, 109-2, 109-3 and 109-4, respectively. When viewed from a top view, these trench isolation structures 131, 132, 133 and 134 all surround the cell region 100A. Moreover, these trench isolation structures 131, 132, 133 and 134 may independently have a continuous or discontinuous ring on a plane (for example, the XY plane). As shown in FIG. 2, in one embodiment, these trench isolation structures 131, 132, 133 and 134 penetrate through the JTE structure 113, such as penetrate through the inner doped region 113A of the JTE structure 113, and are extended downward into the ring-shaped doped regions 109-1, 109-2, 109-3 and 109-4. According to some embodiments of the present disclosure, multiple trenches of these trench isolation structures 131, 132, 133 and 134, and the trench 120 in the cell region 100A may be fabricated simultaneously by the same etching process using the same photo mask. In addition, the trenches of the trench isolation structures 131, 132, 133 and 134 may be filled with a dielectric material layer 125 that is used to form a gate dielectric layer 126. The bottom surfaces of the trench isolation structures 131, 132, 133 and 134 and the bottom surface of the trench 120 in the cell region 100A may be at the same level L1 in the height. The details of other features of the semiconductor device 100 of FIG. 2 may refer to the aforementioned description of the semiconductor device 100 of FIG. 1, which is not repeated here. According to an embodiment of the present disclosure, in the semiconductor device 100 of FIG. 2, the doping concentration of the JTE structure 113 may be the same as that of these ring-shaped doped regions 109-1, 109-2, 109-3 and 109-4 of the buried guard ring 109. In another embodiment, in the semiconductor device 100 of FIG. 2, the doping concentration of the JTE structure 113 may be lower than that of these ring-shaped doped regions 109-1, 109-2, 109-3 and 109-4 of the buried guard ring 109.

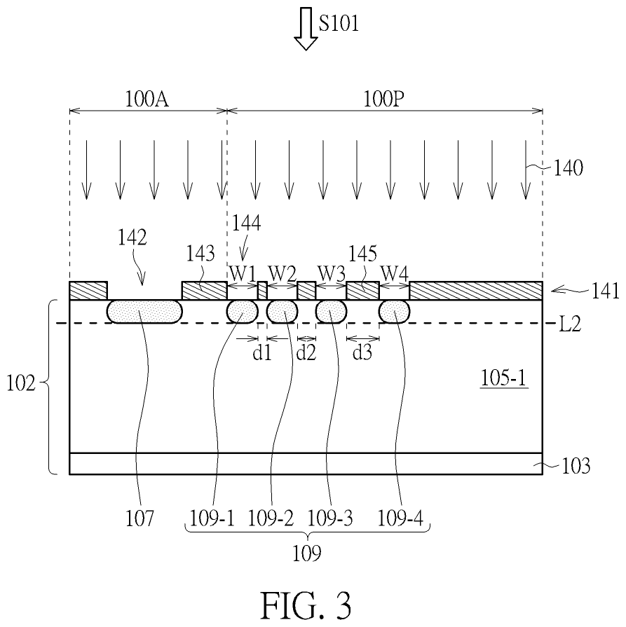

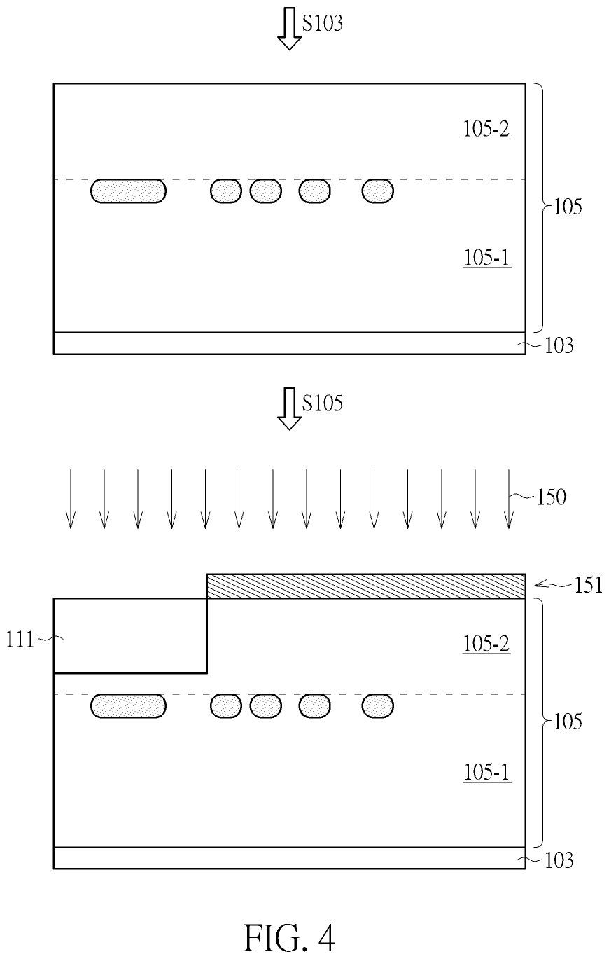

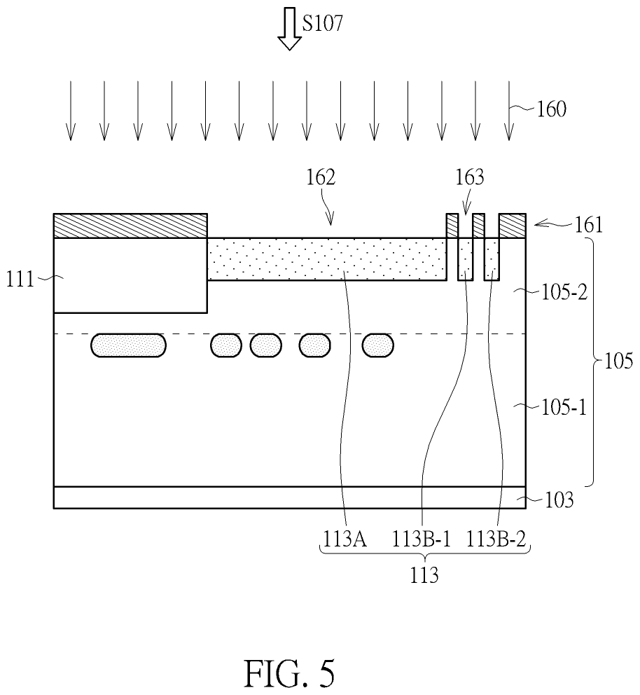

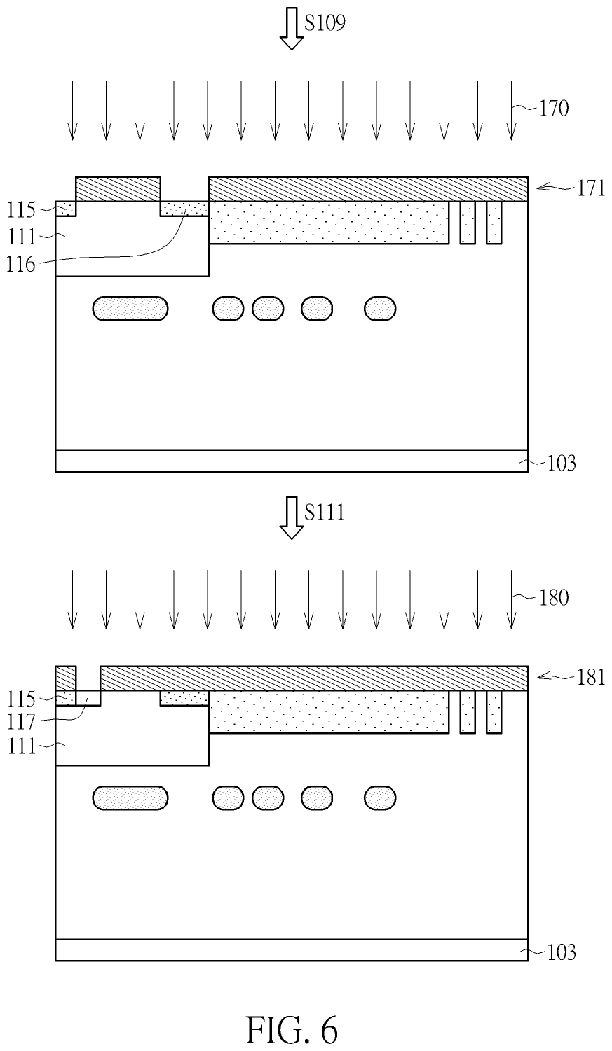

FIG. 3, FIG. 4, FIG. 5, FIG. 6, FIG. 7 and FIG. 8 are schematic cross-sectional views of some stages of a method of fabricating the semiconductor device 100 according to an embodiment of the present disclosure. Referring to FIG. 3, firstly, a wafer 102 is provided, which includes a first epitaxial layer 105-1 having the first conductivity type deposited on a drain contact region 103. The drain contact region 103 is, for example, an N-type heavily doped region, which is formed on the backside of the wafer 102 by an ion implantation process. The first epitaxial layer 105-1 is, for example, an N-type lightly doped SiC epitaxial layer, which is formed by an epitaxial growth process. The wafer 102 includes a cell region 100A and a termination region 100P. In step S101, a patterned hard mask 141 is formed on the first epitaxial layer 105-1 by photolithography and etching processes. The composition of the patterned hard mask 141 is, for example, silicon oxide or silicon nitride. The patterned hard mask 141 has an opening 142 in the cell region 100A, multiple openings 144 in the termination region 100P, a shielding portion 143 between the opening 142 and the openings 144, and multiple shielding portions 145 between the multiple openings 144. The opening 142 in the cell region 100A corresponds to a predetermined region of forming a shielding doped region, and the multiple openings 144 in the termination region 100P correspond to a predetermined region of forming multiple laterally separated ring-shaped doped regions. Next, through the opening 142 and the multiple openings 144 of the patterned hard mask 141, a first ion implantation process 140 is performed on the first epitaxial layer 105-1, so as to simultaneously form a shielding doped region 107 in the cell region 100A, and a buried guard ring 109 in the termination region 100P, where the buried guard ring 109 includes multiple laterally separated ring-shaped doped regions 109-1, 109-2, 109-3 and 109-4. The shielding doped region 107 and these ring-shaped doped regions 109-1, 109-2, 109-3 and 109-4 all have the second conductivity type, which are for example P-type heavily doped regions. In some embodiments, the doping concentrations of both the shielding doped region 107 and the buried guard ring 109 are about 1E19 to 1E20 atoms/cm³.

According to some embodiments of the present disclosure, the shielding doped region 107 and the ring-shaped doped regions 109-1, 109-2, 109-3 and 109-4 of the buried guard ring 109 formed by the same first ion implantation process 140 have substantially the same doping concentration and the same level in the height. For example, the bottom surface of the shielding doped region 107 and the bottom surfaces of these ring-shaped doped regions 109-1, 109-2, 109-3 and 109-4 are at the same level L2 in the height. In addition, the widths W1, W2, W3 and W4 and the spacing widths d1, d2 and d3 of the ring-shaped doped regions 109-1, 109-2, 109-3 and 109-4 may be adjusted according to the electric field distribution of the semiconductor device 100 and through the widths of the multiple openings 144 and the widths of the multiple shielding portions 145 of the patterned hard mask 141. Accordingly, the electric field in the termination region 100P is effectively reduced by the buried guard ring 109, thereby enhancing the breakdown voltage of the semiconductor device 100.

After the shielding doped region 107 and the buried guard ring 109 are formed, a stripping process, such as acid soaking or ashing process may be used to remove the patterned hard mask 141. Afterwards, referring to FIG. 4, in step S103, a second epitaxial layer 105-2 is deposited on the first epitaxial layer 105-1 by another epitaxial growth process to cover the shielding doped region 107 and the buried guard ring 109. The second epitaxial layer 105-2 also has the first conductivity type and is, for example, an N-type lightly doped SiC epitaxial layer. The first epitaxial layer 105-1 and the second epitaxial layer 105-2 may be together referred to as an epitaxial layer 105.

Next, still referring to FIG. 4, in step S105, a patterned hard mask 151 is formed on the second epitaxial layer 105-2 by photolithography and etching processes. The composition of the patterned hard mask 151 is, for example, silicon oxide or silicon nitride. Then, an ion implantation process 150 is performed on the second epitaxial layer 105-2 through the opening of the patterned hard mask 151 to form a well region 111 in the cell region 100A. The well region 111 has the second conductivity type and is, for example a P-type well region. The well region 111 is formed directly above the shielding doped region 107. Moreover, the well region 111 and the shielding doped region 107 are separated from each other in the depth direction of the epitaxial layer 105. After the well region 111 is formed, the patterned hard mask 151 is removed by a stripping process.

Afterwards, referring to FIG. 5, in step S107, another patterned hard mask 161 is formed on the second epitaxial layer 105-2 by photolithography and etching processes. The patterned hard mask 161 has multiple openings 162 and 163 located in the termination region 100P, where the opening 162 corresponds to a predetermined region of forming an inner doped region of the JTE structure, and the multiple openings 163 correspond to a predetermined region of forming multiple laterally separated outer doped regions of the JTE structure. Next, through the openings 162 and 163 of the patterned hard mask 161, a second ion implantation process 160 is performed on the second epitaxial layer 105-2 to simultaneously form the inner doped region 113A and multiple laterally separated outer doped regions 113B-1 and 113B-2 of the JTE structure 113 in the second epitaxial layer 105-2 at the termination region 100P. The inner doped region 113A abuts to the well region 111 of the cell region 100A. According to some embodiments of the present disclosure, the JTE structure 113 is formed directly above the buried guard ring 109 and separated from the buried guard ring 109 in the depth direction of the epitaxial layer 105. The inner doped region 113A and the multiple outer doped regions 113B-1 and 113B-2 of the JTE structure 113 all have the second conductivity type and the same doping concentration, for example, they are P-type doped regions. In one embodiment, the dopant dose used in the second ion implantation process 160 is lower than the dopant dose used in the first ion implantation process 140, so that the doping concentration of the JTE structure 113 is lower than that of the buried guard ring 109. The doping concentration of the JTE structure 113 is, for example, about 1E17 to 1E18 atoms/cm³. In other embodiments, the dopant dose used in the second ion implantation process 160 may be adjusted, so that the doping concentration of the JTE structure 113 is equal to or higher than that of the buried guard ring 109. In addition, the area of the inner doped region 113A of the JTE structure 113 may be controlled by adjusting the width of the opening 162 of the patterned hard mask 161, and the number of the multiple outer doped regions 113B-1 and 113B-2 of the JTE structure 113 may be controlled by adjusting the number of the multiple openings 163 of the patterned hard mask 161 according to the electric field distribution of the semiconductor device 100. Therefore, the surface electric field at the termination region 100P is effectively reduced by the JTE structure 113, thereby enhancing the breakdown voltage of the semiconductor device 100. After the JTE 113 is formed, the patterned hard mask 161 is removed by a stripping process.

Afterwards, referring to FIG. 6, in step S109, a patterned hard mask 171 is formed on the second epitaxial layer 105-2 by photolithography and etching processes. Then, through the opening of the patterned hard mask 171, an ion implantation process 170 is performed on second epitaxial layer 105-2 to form a bulk contact region 115 and a heavily doped region 116 in the well region 111. The bulk contact region 115 and the heavily doped region 116 have the second conductivity type, which are, for example P-type heavily doped regions. Afterwards, the patterned hard mask 171 is removed by a stripping process.

Next, still referring to FIG. 6, in step S111, another patterned hard mask 181 is formed on the second epitaxial layer 105-2 by photolithography and etching processes. Then, through the opening of the patterned hard mask 181, an ion implantation process 180 is performed on the second epitaxial layer 105-2 to form a source contact region 117 in the well region 111. The source contact region 117 has the first conductivity type and is, for example an N-type heavily doped region, which abuts the bulk contact region 115. Thereafter, the patterned hard mask 181 is removed by a stripping process.

Afterwards, referring to FIG. 7, in step S113, another patterned hard mask 191 is formed on the second epitaxial layer 105-2. Then, through the opening of the patterned hard mask 191, an etching process is performed on the second epitaxial layer 105-2 in the cell region 100A to form a trench 120 that passes through the well region 111 and the second epitaxial layer 105-2, and is extended into the shielding doped region 107. The source contact region 117 and the heavily doped region 116 are respectively located on both sides of the trench 120. Thereafter, the patterned hard mask 191 is removed by a stripping process. In addition, after removing the patterned hard mask 191, a sacrificial oxide layer may be formed on the sidewalls and the bottom surface of the trench 120 by a thermal oxidation process. Then, the sacrificial oxide layer may be removed by an acid soaking process to repair the surface defects on the sidewalls and the bottom surface of the trench 120 produced by the etching process, which is beneficial to improve the quality of a gate dielectric layer subsequently formed in the trench 120.

Next, still referring to FIG. 7, in step S115, a dielectric material layer 125 such as a silicon oxide layer, is conformally deposited on the sidewalls and the bottom surface of the trench 120 and on the surface of the second epitaxial layer 105-2. The dielectric material layer formed on the sidewalls and the bottom surface of the trench 120 is used as a gate dielectric layer 126. Then, a conductive material such polysilicon is completely deposited on the dielectric material layer 125, fills up the trench 120 and covers the gate dielectric layer 126. Next, an etching-back process is performed to remove the conductive material outside the trench 120 to form a gate electrode 127 in the trench 120. In one embodiment, the top surface of the gate electrode 127 may be level with or lower than the top surfaces of the source contact region 117 and the heavily doped region 116.

Afterwards, referring to FIG. 8, in step S117, an interlayer dielectric (ILD) layer 130 is fully deposited on the epitaxial layer 105. Then, multiple contact openings 155 and 157 are formed in the ILD layer 130 by photolithography and etching processes. A portion of the source contact region 117 and a portion of the bulk contact region 115 are exposed through the contact opening 155, and a portion of the heavily doped region 116 is exposed through the contact opening 157. In addition, other contact openings (not shown) may be formed in the ILD layer 130, so as to form multiple contacts electrically coupled to the gate electrode 127, the JTE structure 113 and the buried guard ring 109 respectively.

Next, still referring to FIG. 8, in step S119, a metal material may be conformally deposited on the surface of the ILD layer 130 and in the contact openings 155 and 157. Then, a metal silicide is formed by the reaction between the metal material and the material of the epitaxial layer using a rapid thermal annealing process. Thereafter, the unreacted metal material is removed, and a barrier layer (not shown) is formed on the sidewalls and the bottom surfaces of the contact openings 155 and 157. Afterwards, a conductive material is deposited on the ILD layer 130 by a deposition process. The conductive material fills up the contact openings 155 and 157 to form the vias 135 and 137. Then, the conductive material is patterned by photolithography and etching processes to form a metal wire layer including a source electrode 136 on the ILD layer 130. The source electrode 136 is electrically coupled to the source contact region 117 and the bulk contact region 115 through the via 135, and the source electrode 136 is also electrically coupled to the heavily doped region 116 through the via 137. In one embodiment, the metal material of forming the barrier layer is, for example, tantalum (Ta), tantalum nitride (TaN), titanium (Ti), titanium nitride (TiN) or other suitable diffusion barrier materials. The conductive material of forming the vias 135 and 137 and the source electrode 136 is, for example, aluminum copper (AlCu), aluminum (Al), copper (Cu) or other suitable conductive metal materials. In addition, in step S119, other vias and metal wires may also be formed at the same time, so as to be electrically coupled to the gate electrode 127, the JTE structure 113 and the buried guard ring 109 respectively. Moreover, the JTE structure 113 and the buried guard ring 109 may be further electrically coupled to the source electrode 136 or a ground terminal, such that the JTE structure 113 and the buried guard ring 109 may further reduce the surface electric field of the semiconductor device 100 to enhance the breakdown voltage thereof. Afterwards, a drain electrode 138 may be formed on the bottom surface of the drain contact region 103 by a deposition process to complete the semiconductor device 100 of FIG. 1.

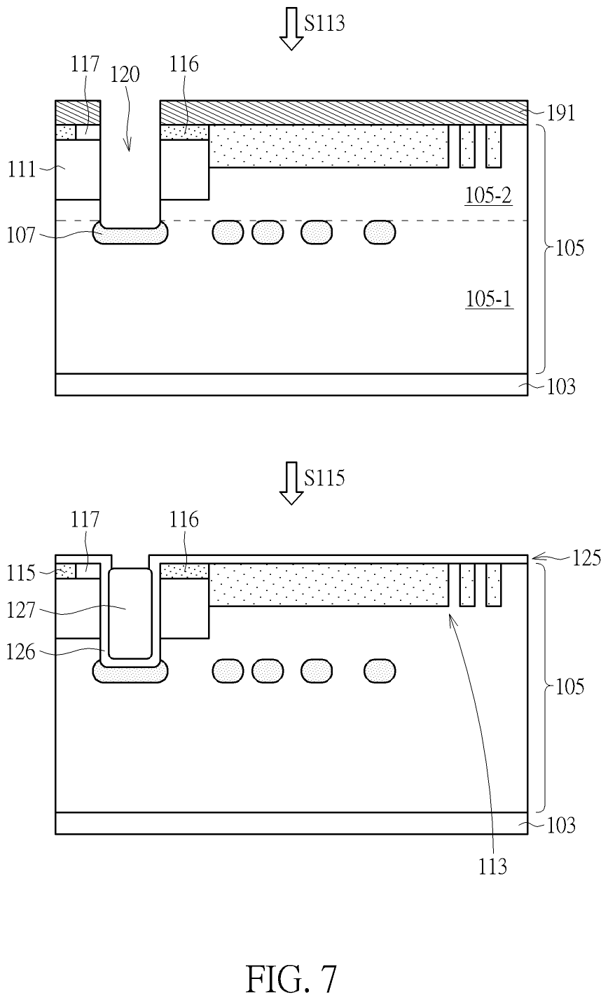

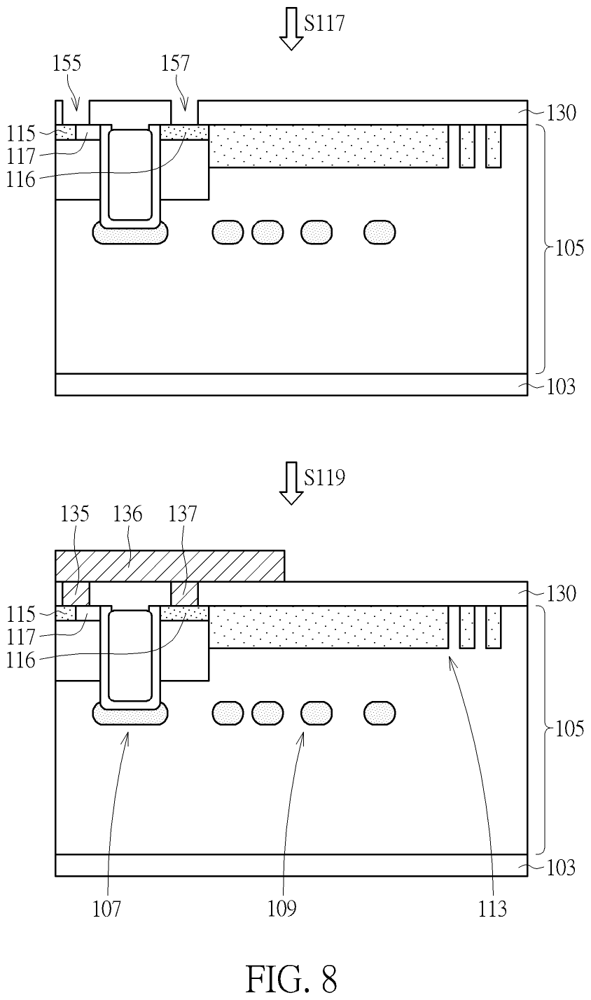

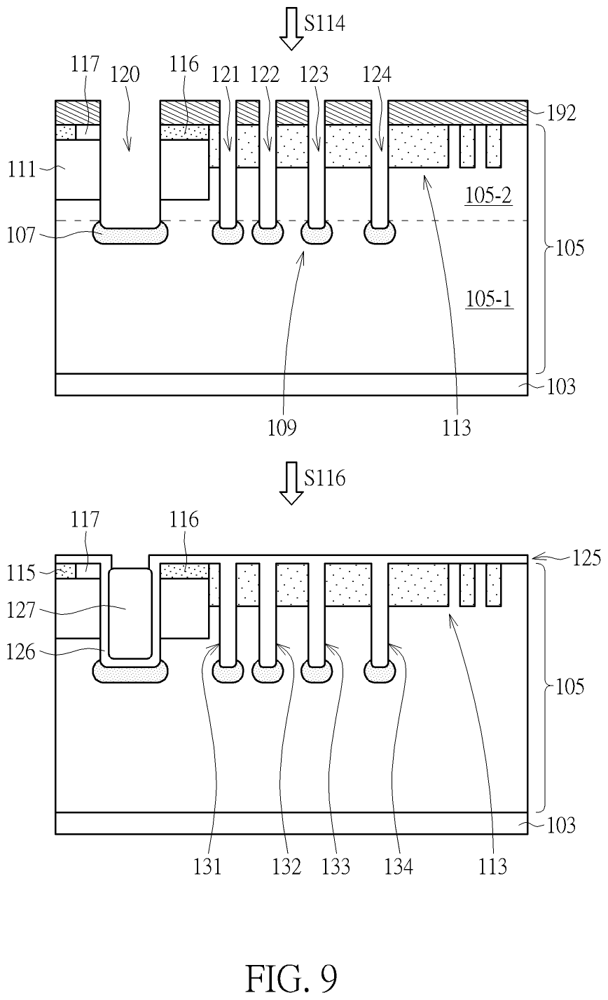

FIG. 9 shows schematic cross-sectional views of some intermediate stages of a method of fabricating the semiconductor device 100 of FIG. 2 according to another embodiment of the present disclosure. In this embodiment, before step S114 in FIG. 9, the aforementioned steps in FIG. 3, FIG. 4, FIG. 5 and FIG. 6 are performed. After the step S111 in FIG. 6, referring to FIG. 9, in step S114, a patterned hard mask 192 is formed on the second epitaxial layer 105-2. Then, an etching process is performed on the second epitaxial layer 105-2 in the cell region 100A and the termination region 100P through multiple openings of the patterned hard mask 192, so as to simultaneously form a trench 120 in the cell region 100A and multiple ring-shaped trenches 121, 122, 123 and 124 in the termination region 100P. The trench 120 passes through the well region 111 and the second epitaxial layer 105-2, and is further extended downward into the shielding doped region 107. The multiple ring-shaped trenches 121, 122, 123 and 124 pass through the inner doped region 113A of the JTE structure 113 and the second epitaxial layer 105-2, and are further extended downward into the multiple ring-shaped doped regions 109-1, 109-2, 109-3 and 109-4 of the buried guard ring 109. In this embodiment, the trench 120 is formed directly above the shielding doped region 107, and the multiple ring-shaped trenches 121, 122, 123, 124 are formed directly above the buried guard ring 109 at the same time. Afterwards, the patterned hard mask 192 is removed using a stripping process.

Next, still referring to FIG. 9, in step S116, a dielectric material layer 125 such as a silicon oxide layer is deposited on the sidewalls and the bottom surface of the trench 120, and also on the surface of the epitaxial layer 105. In addition, the dielectric material layer 125 fills up the multiple ring-shaped trenches 121, 122, 123 and 124 to form multiple trench isolation structures 131, 132, 133 and 134. The dielectric material layer formed on the sidewalls and the bottom surface of the trench 120 is used as a gate dielectric layer 126. After the step S116 in FIG. 9, the aforementioned steps S117 and S119 in FIG. 8 are performed to complete the semiconductor device 100 of FIG. 2.

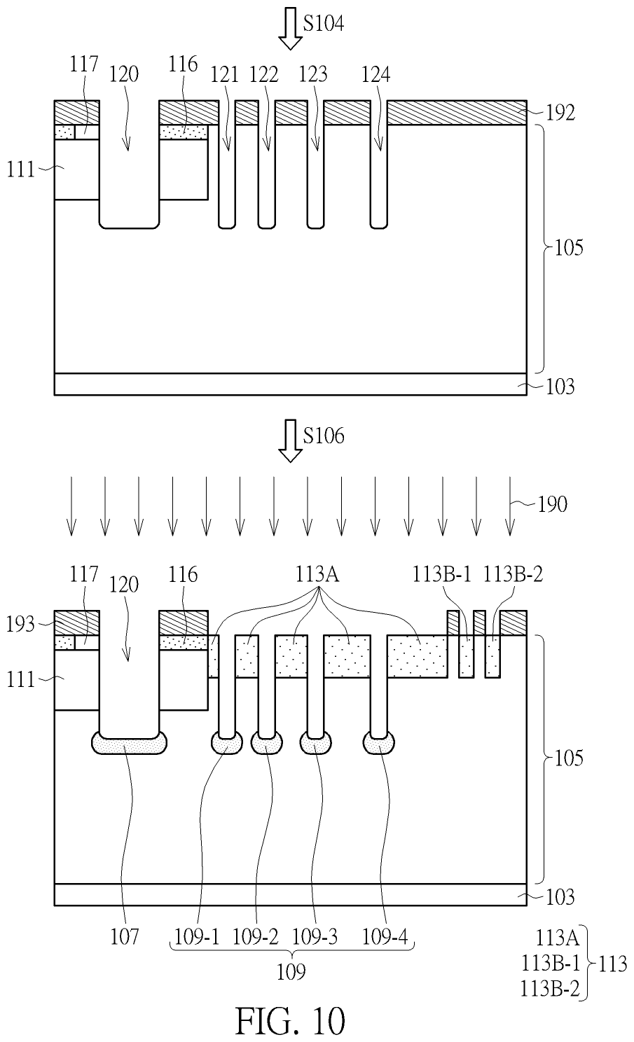

FIG. 10 shows schematic cross-sectional views of some intermediate stages of a method of fabricating the semiconductor device 100 of FIG. 2 according to further another embodiment of the present disclosure. In this embodiment, refer to the aforementioned steps in FIG. 3 and FIG. 4, before the step S101 of forming the shielding doped region 107 and the buried guard ring 109, an epitaxial growth process is performed to form an epitaxial layer 105 on the drain contact region 103. In this embodiment, a first epitaxial layer 105-1 and a second epitaxial layer 105-2 are not formed separately, and the epitaxial layer 105 may be formed by using one epitaxial growth process. Afterwards, the well region 111, the source contact region 117, the bulk contact region 115 and the heavily doped region 116 are formed by using the aforementioned steps in FIG. 4 and FIG. 6. In one embodiment, before step S104 in FIG. 10, the JTE structure 113 and the buried guard ring 109 have not been formed in the epitaxial layer 105 of the termination region 100P, and the shielding doped region 107 has not been formed in the epitaxial layer 105 of the cell region 100A. Next, referring to FIG. 10, in step S104, a patterned hard mask 192 is formed on the epitaxial layer 105. Then, an etching process is performed on the epitaxial layer 105 of both the cell region 100A and the termination region 100P through multiple openings of the patterned hard mask 192 to simultaneously form a trench 120 in the cell region 100A and multiple ring-shaped trenches 121, 122, 123 and 124 in the termination region 100P. The trench 120 passes through the well region 111 and is extended downward. The bottom surface of the trench 120 and the bottom surfaces of the multiple ring-shaped trenches 121, 122, 123 and 124 may be at the same depth in the epitaxial layer 105. Afterwards, the patterned hard mask 192 is removed by using a stripping process.

Next, still referring to FIG. 10, in step S106, another patterned hard mask 193 is formed on the epitaxial layer 105. The patterned hard mask 193 has multiple openings respectively exposing predetermined regions of forming the trench 120, and the inner doped region 113A and the multiple outer doped regions 113B-1 and 113B-2 of the JTE structure 113. Then, an ion implantation process 190 is performed on the epitaxial layer 105 through the openings of the patterned hard mask 193, the trench 120, and the multiple ring-shaped trenches 121, 122, 123 and 124, so that a shielding doped region 107 is formed directly below the trench 120 in the cell region 100A, and multiple ring-shaped doped regions 109-1, 109-2, 109-3 and 109-4 of the buried guard ring 109 are simultaneously formed directly below the multiple ring-shaped trenches 121, 122, 123 and 124 in the termination region 100P. In addition, the inner doped region 113A and the outer doped regions 113B-1 and 113B-2 of the JTE structure 113 are simultaneously formed in the termination region 100P. In this embodiment, the shielding doped region 107, the JTE structure 113 and the buried guard ring 109 may be formed by the same ion implantation process 190 and have substantially the same doping concentration. Afterwards, the patterned hard mask 193 is removed by a stripping process. After the step S106 in FIG. 10 is performed, the aforementioned step S116 in FIG. 9 and the aforementioned steps S117 and S119 in FIG. 8 are performed to complete the semiconductor device 100 of FIG. 2. In this embodiment, the epitaxial layer 105 may be formed by one epitaxial growth process, and the shielding doped region 107, the JTE structure 113 and the buried guard ring 109 may be formed simultaneously by the same ion implantation process, thereby decreasing the process steps of fabricating the semiconductor device 100 of FIG. 2, and further reducing the fabrication cost thereof.

According to some embodiments of the present disclosure, the junction termination extension structure and the buried guard ring are combined in the termination region of the semiconductor device, so that the overall depletion region in the termination region is extended and enlarged to effectively reduce the electric field at the end of the main junction in the cell region and the surface electric field in the termination region. Therefore, under the condition of maintaining the same breakdown voltage, the width of the termination region required by the semiconductor device is greatly shortened. For example, compared with the width of the termination region required by the conventional termination structure, the width of the termination region of the semiconductor devices of the present disclosure may be decreased to less than a quarter of that of the conventional termination structure, thereby reducing the die area.

In addition, according to some embodiments of the present disclosure, the buried guard ring and the shielding doped region of the semiconductor devices may be formed simultaneously through the same ion implantation process by using the same photo mask, thereby reducing the cost of fabricating the semiconductor devices.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, having a first conductivity type and comprising a cell region and a termination region;
a trench, disposed in the substrate and located in the cell region;
a gate electrode, disposed in the trench;
a shielding doped region, having a second conductivity type, disposed in the substrate and located directly below the trench;
a buried guard ring, having the second conductivity type, disposed in the substrate and located in the termination region, wherein the buried guard ring and the shielding doped region are at the same depth in the substrate; and
a junction termination extension structure, having the second conductivity type, disposed in the substrate, located directly above the buried guard ring, and separated from the buried guard ring.

2. The semiconductor device of claim 1, wherein the junction termination extension structure comprises an inner doped region and a plurality of laterally separated outer doped regions, and the inner doped region and the plurality of laterally separated outer doped regions have the same doping concentration.

3. The semiconductor device of claim 2, wherein a vertical projection area of the plurality of laterally separated outer doped regions is outside a vertical projection area of the buried guard ring.

4. The semiconductor device of claim 2, wherein an outermost edge of the inner doped region is farther away from the cell region than an outermost edge of the buried guard ring.

5. The semiconductor device of claim 1, wherein the buried guard ring comprises a plurality of laterally separated ring-shaped doped regions, and doping concentrations of the plurality of laterally separated ring-shaped doped regions are the same as a doping concentration of the shielding doped region.

6. The semiconductor device of claim 5, wherein a plurality of spacing between the plurality of laterally separated ring-shaped doped regions are gradually increased in a direction from the cell region to the termination region.

7. The semiconductor device of claim 5, wherein the plurality of laterally separated ring-shaped doped regions have the same width.

8. The semiconductor device of claim 5, further comprising a plurality of trench isolation structures disposed in the substrate and located in the termination region, wherein the plurality of trench isolation structures are correspondingly disposed directly above the plurality of laterally separated ring-shaped doped regions.

9. The semiconductor device of claim 8, wherein the plurality of trench isolation structures pass through the junction termination extension structure, and bottom surfaces of the plurality of trench isolation structures are at the same level in the height with a bottom surface of the trench.

10. The semiconductor device of claim 1, wherein a doping concentration of the junction termination extension structure is lower than a doping concentration of the buried guard ring.

11. The semiconductor device of claim 1, wherein a thickness of the junction termination extension structure is greater than a thickness of the buried guard ring.

12. The semiconductor device of claim 1, wherein the shielding doped region and the buried guard ring are laterally separated from each other, and the buried guard ring and the shielding doped region have the same thickness.

13. The semiconductor device of claim 1, wherein both the buried guard ring and the junction termination extension structure are electrically coupled to a source electrode or a ground terminal.

14. A method of fabricating a semiconductor device, comprising:
providing a substrate comprising an epitaxial layer having a first conductivity type, wherein the substrate comprises a cell region and a termination region;
performing an ion implantation process on the epitaxial layer to form a shielding doped region in the cell region, and a buried guard ring and a junction termination extension structure in the termination region, wherein the junction termination extension structure is located directly above the buried guard ring and separated from the buried guard ring, and the shielding doped region, the buried guard ring and the junction termination extension structure all have a second conductivity type;
forming a trench in the epitaxial layer and in the cell region; and
forming a gate electrode in the trench.

15. The method of claim 14, wherein the epitaxial layer comprises a first epitaxial layer and a second epitaxial layer stacked from bottom to top, the second epitaxial layer covers the shielding doped region and the buried guard ring, and the junction termination extension structure is formed in the second epitaxial layer.

16. The method of claim 14, wherein forming the junction termination extension structure comprises simultaneously forming an inner doped region and a plurality of laterally separated outer doped regions, and forming the buried guard ring comprises simultaneously forming a plurality of laterally separated ring-shaped doped regions, doping concentrations of the plurality of laterally separated ring-shaped doped regions are the same as a doping concentration of the shielding doped region, and the plurality of laterally separated ring-shaped doped regions and the shielding doping region are at the same level in the height.

17. The method of claim 14, wherein the step of forming the trench further comprises simultaneously forming a plurality of ring-shaped trenches in the epitaxial layer and located in the termination region, the trench is formed directly above the shielding doped region, and the plurality of ring-shaped trenches are formed directly above the buried guard ring.

18. The method of claim 17, wherein the ion implantation process comprises a first ion implantation process and a second ion implantation process, the shielding doped region and the buried guard ring are simultaneously formed by the first ion implantation process, the junction termination extension structure is formed by the second ion implantation process, and the trench and the plurality of ring-shaped trenches are formed after the shielding doped region, the buried guard ring and the junction termination extension structure are formed.

19. The method of claim 17, wherein the shielding doped region, the buried guard ring and the junction termination extension structure are simultaneously formed by the ion implantation process, and the trench and the plurality of ring-shaped trenches are formed before forming the shielding doped region, the buried guard ring and the junction termination extension structure.

20. The method of claim 17, further comprising conformally depositing a dielectric material layer on sidewalls and a bottom surface of the trench to form a gate dielectric layer, wherein the dielectric material layer further fills up the plurality of ring-shaped trenches to form a plurality of trench isolation structures.
